(19) United States
(12) Patent Application Publication
(10) Pub. No.: US 2018/0038924 A1
(43) Pub. Date: Feb. 8, 2018

(54) MEANS AND METHOD OF MAGNETIC RESONANCE IMAGING OF SAMPLES AND PROCESSES AT HIGH TEMPERATURES AND HIGH PRESSURES

(71) Applicant: ASPECT IMAGING LTD., SHOHAM (IL)

(72) Inventors: Uri RAPOPORT, Moshav Ben Shemen (IL); Tal COHEN, Herzlia (IL); Itay BARUCHI, Tel Aviv (IL)

(21) Appl. No.: 15/228,464

(22) Filed: Aug. 4, 2016

(51) Int. Cl. G01R 33/30; G01N 24/08; G01R 33/31

(52) U.S. Cl. CPC G01R 33/305; G01R 33/31; G01N 24/081; G01N 24/088

(57) ABSTRACT

MRI/NMR systems, devices and modules thereof for T1/T2 analysis; FT spectroscopy; CW spectroscopy and 2D/3D imaging of samples, process and reactions at high temperatures and/or high pressures, comprising active and/or passive thermal insulating means as described in the description and figures.

### FIELD OF THE INVENTION

The present invention generally pertains to MRI/NMR systems, devices and modules thereof, and to both online and offline methods of magnet resonance imaging of samples, reactions and processes at high temperatures and/or high pressures.

### BACKGROUND OF THE INVENTION

Magnetic resonance imaging of samples at both high temperature and high pressure conditions are extremely complicated and provided a motive for several studies.

Hence, for example, U.S. Pat. No. 8,791,695 by Balcom et al., which is incorporated herein as a reference, discloses that MRI has been used in oil and gas exploration where reservoir rock core samples are analyzed to obtain information about the nature of the reservoir being investigated. In the ground, the reservoir rock can be under tremendous pressure and elevated temperatures. It is desirable to reproduce such reservoir conditions when performing tests on reservoir rock core samples. In order to do so, however, the core holder which houses the core sample must be capable of withstanding elevated pressures and temperatures as found in reservoirs. This presents challenges as to the materials that can be used for the holder. Metal core holders are known which are capable of withstanding elevated pressures and temperatures. Metal core holders, however, block the nuclear magnetic resonance (NMR) signal in the core sample from being detected in the RF probe. In addition, the rapidly switched magnetic field gradients induct currents in the metal called eddy currents. These eddy currents distort the magnetic field and thus distort the resultant magnetic resonance image.

U.S. Pat. No. 7,352,179 by Green Imaging Technologies Inc., which is incorporated herein as a reference, discloses method and apparatus are provided for measuring a parameter such as capillary pressure in porous media such as rock samples. The method comprises mounting a sample in a centrifuge such that different portions of the sample are spaced at different distances from the centrifuge axis, rotating the sample about the axis, measuring a first parameter in the different portions of the sample, and determining the value of a second parameter related to the force to which each portion is subjected due to rotation of the sample. In one embodiment, the first parameter is relative saturation of the sample as measured by MRI techniques, and the second parameter is capillary pressure.

U.S. Pat. No. 6,507,191 by Jeol Ltd., which is incorporated herein as a reference, discloses an NMR cell system for supercritical fluid measurements, said NMR cell system comprising: a cylindrical cell having a bottom and receiving a sample, said cell having an open end; a cell holder mounted at the open end of said cylindrical cell; an external pumping system comprising a vacuum pump for evacuating the inside of said cylindrical cell before introducing a sample and a pressure pump for introducing a sample into said cylindrical cell after the evacuation and applying pressure to the sample; and a pipe mounted in said cell holder and acting to connect said external pumping system into said cylindrical cell, said pipe configured for evacuating said cell and introducing a sample.

It is thus a long felt need to disclose MR devices (MRD), such as MRI and NMR, and modules thereof, and to both online and offline methods of magnet resonance imaging of samples, reactions and processes at high temperatures and/or high pressures.

### SUMMARY OF THE INVENTION

One object of the invention is to disclose MRI/NMR systems, devices and modules thereof for T1/T2 analysis; FT spectroscopy; CW spectroscopy and 2D/3D imaging of samples, process and reactions at high temperatures and/or high pressures, comprising active and/or passive thermal insulating means as described in the description and figures.

Another object of the invention is to disclose MRI/NMR systems, devices and modules thereof for T1/T2 analysis; FT spectroscopy; CW spectroscopy and 2D/3D imaging of samples, process and reactions at high temperatures and/or high pressures, comprising active and/or passive SNR increasing means as described in the description and figures.

Another object of the invention is to disclose a method of providing T1/T2 analysis; FT spectroscopy; CW spectroscopy and 2D/3D imaging of samples, process and reactions at high temperatures and/or high pressures, comprising step of inline or offline active and/or passive thermal insulating the same as described in the description and figures.

Another object of the invention is to disclose a method of providing T1/T2 analysis; FT spectroscopy; CW spectroscopy and 2D/3D imaging of samples, process and reactions at high temperatures and/or high pressures, comprising step of inline or offline active and/or passive SNR increasing the same as described in the description and figures.

### DETAILED DESCRIPTION OF THE PREFERRED EMBODIMENTS

According to an embodiment of the invention, the term ‘high temperature(s)’ refers to any temperature higher ambient temperature, and especially to temperature higher than magnets' temperature. In a particular embodiment of the invention, high temperature is higher a temperature (in Celsius degrees) about 40 C, wherein the term ‘about’ refers hereinafter to any value being up to 25% higher or 25% lower a defined measure. In another particular embodiment of the invention, high temperature is higher about water boiling point. In another particular embodiment of the invention, high temperature is between 100 C to 220 C. In another particular embodiment of the invention, high temperature is higher about 220 C.

According to an embodiment of the invention, the term ‘high pressure(s)’ refers to any pressure higher an ambient pressure. In a particular embodiment of the invention, high pressure (in Atmospheres) is higher about 1 Atm. In another particular embodiment of the invention, high pressure is between about 1 to about 2.5 Atm. In another particular embodiment of the invention, high pressure is between about 2.2 to about 220 Atm. In another particular embodiment of the invention, high pressure is between about 220 to about 620 Atm. In another particular embodiment of the invention, high pressure is above about 600 Atm.

According to an embodiment of the invention, the term ‘low pressure(s)’ refers to any pressure higher ambient pressure. In a particular embodiment of the invention, low pressure is lower an ambient pressure, e.g., lower 1 Atm. In another particular embodiment of the invention, low pressure is between about 0.01 to about 1 Atm. In another particular embodiment of the invention, low pressure is lower about 0.01.

The term “heat pipe” refers hereinafter to heat-transfer device that combines the principles of both thermal conductivity and phase transition to efficiently manage the transfer of heat between two solid interfaces.

It is in the scope of the invention wherein at the hot interface of a heat pipe a liquid in contact with a thermally conductive solid surface turns into a vapor by absorbing heat from that surface. The vapor then travels along the heat pipe to the cold interface and condenses back into a liquid—releasing the latent heat. The liquid then returns to the hot interface through either capillary action, centrifugal force, or gravity, and the cycle repeats. Due to the very high heat transfer coefficients for boiling and condensation, heat pipes are highly efficient thermal conductors. The effective thermal conductivity varies with heat pipe length, and can approach 100,000 W/(m·K) for long heat pipes, in comparison with approximately 400 W/(m·K) for copper. It

It is also in the scope of the invention wherein a heat pipe consists of a sealed pipe or tube made of a material that is compatible with the working fluid such as copper for water heat pipes, or aluminum for ammonia heat pipes. A vacuum pump is useable to remove the air from the empty heat pipe. The heat pipe is partially filled with a working fluid and then sealed. The working fluid mass is chosen so that the heat pipe contains both vapor and liquid over the operating temperature range. Water heat pipes possibly filled by partially filling with water, heating until the water boils and displaces the air, and then sealed while hot.

It is in the scope of eth invention wherein glycol is used as process fluid. More than that, its temperature sensitivity is also useable; see for example U.S. Pat. No. 7,489,132, Enhanced heat transfer in MRI gradient coils with phase-change materials; U.S. Pat. No. 7,570,058, System and method for treatment of liquid coolant in an MRI system; and Doble, Dan M J, et al. “Optimization of the relaxivity of MRI contrast agents: Effect of poly (ethylene glycol) chains on the water-exchange rates of GdIII complexes.” Journal of the American Chemical Society 123.43 (2001): 10758-10759 all incorporated herein as a reference.

It is also in the scope of the invention wherein working fluids are chosen according to the temperatures at which the heat pipe must operate, with examples ranging from liquid helium for extremely low temperature applications (2 to 4 K) to mercury (523 to 923 K), sodium (873 to 1473 K) and even indium (2000 to 3000 K) for extremely high temperatures. The vast majority of heat pipes for room temperature applications use ammonia (213 to 373 K), alcohol (methanol (283 to 403 K) or ethanol (273 to 403 K)) or water (298 to 573 K) as the working fluid. Copper/water heat pipes have a copper envelope, use water as the working fluid and typically operate in the temperature range of 20 to 150° C.

It is also in the scope of the invention wherein for the heat pipe to transfer heat, it contain saturated liquid and its vapor (gas phase). The saturated liquid vaporizes and travels to the condenser, where it is cooled and turned back to a saturated liquid. The condensed liquid is possibly returned to the evaporator using a wick structure exerting a capillary action on the liquid phase of the working fluid. Wick structures used in heat pipes include sintered metal powder, screen, and grooved wicks, which have a series of grooves parallel to the pipe axis. When the condenser is located above the evaporator in a gravitational field, gravity can return the liquid. In this case, the heat pipe is a thermosyphon. Finally, rotating heat pipes use centrifugal forces to return liquid from the condenser to the evaporator.

It is also in the scope of the invention wherein heat pipes contain no mechanical moving parts and typically require no maintenance, though non-condensable gases that diffuse through the pipe's walls, resulting from breakdown of the working fluid or as impurities extant in the material, may eventually reduce the pipe's effectiveness at transferring heat.

It is also in the scope of the invention wherein the advantage of heat pipes over many other heat-dissipation mechanisms is their great efficiency in transferring heat. A pipe one inch in diameter and two feet long can transfer 12,500 BTU (3.7 kWh) per hour at 1,800° F. (980° C.) with only 18° F. (10° C.) drop from end to end. Heat pipes may demonstrated a heat flux of more than 23 kW/cm².

It is also in the scope of the invention wherein heat pipes employ evaporative cooling to transfer thermal energy from one point to another by the evaporation and condensation of a working fluid or coolant. Heat pipes rely on a temperature difference between the ends of the pipe, and cannot lower temperatures at either end beyond the ambient temperature (hence they tend to equalize the temperature within the pipe).

It is also in the scope of the invention wherein when one end of the heat pipe is heated the working fluid inside the pipe at that end evaporates and increases the vapor pressure inside the cavity of the heat pipe. The latent heat of evaporation absorbed by the vaporization of the working fluid reduces the temperature at the hot end of the pipe.

It is also in the scope of the invention wherein the vapor pressure over the hot liquid working fluid at the hot end of the pipe is higher than the equilibrium vapor pressure over the condensing working fluid at the cooler end of the pipe, and this pressure difference drives a rapid mass transfer to the condensing end where the excess vapor condenses, releases its latent heat, and warms the cool end of the pipe. Non-condensing gases (caused by contamination for instance) in the vapor impede the gas flow and reduce the effectiveness of the heat pipe, particularly at low temperatures, where vapor pressures are low. The speed of molecules in a gas is approximately the speed of sound, and in the absence of non-condensing gases (i.e., if there is only a gas phase present) this is the upper limit to the velocity with which they could travel in the heat pipe. In practice, the speed of the vapour through the heat pipe is limited by the rate of condensation at the cold end and far lower than the molecular speed.

It is also in the scope of the invention wherein the condensed working fluid then flows back to the hot end of the pipe. In the case of vertically oriented heat pipes the fluid may be moved by the force of gravity. In the case of heat pipes containing wicks, the fluid is returned by capillary action.

It is also in the scope of the invention wherein making heat pipes, there is no need to create a vacuum in the pipe. One simply boils the working fluid in the heat pipe until the resulting vapor has purged the non-condensing gases from the pipe, and then seals the end.

It is also in the scope of the invention wherein the heat pipes are utilized in a wide effective temperature range. Hence, a heat pipe can operate at hot-end temperatures as low as just slightly warmer than the melting point of the working fluid, although the maximum power is low at temperatures below 25° C. (77° F.). Similarly, a heat pipe with water as a working fluid can work well above the boiling point (100° C., 212° F.). The maximum temperature for long term water heat pipes is 270° C. (518° F.), with heat pipes operating up to 300° C. (572° F.) for short term tests.

It is also in the scope of the invention wherein in heating, ventilation and air-conditioning systems, HVAC, heat pipes are positioned within the supply and exhaust air streams of an air handling system or in the exhaust gases of an industrial process, in order to recover the heat energy.

It is also in the scope of the invention wherein the device consists of a battery of multi-row finned heat pipe tubes located within both the supply and exhaust air streams. Within the exhaust air side of the heat pipe, the refrigerant evaporates, taking its heat from the extract air. The refrigerant vapor moves towards the cooler end of the tube, within the supply air side of the device, where it condenses and gives up its heat. The condensed refrigerant returns by a combination of gravity and capillary action in the wick. Thus heat is transferred from the exhaust air stream through the tube wall to the refrigerant, and then from the refrigerant through the tube wall to the supply air stream.

It is also in the scope of the invention wherein because of the characteristics of the device, better efficiencies are obtained when the unit is positioned upright with the supply air side mounted over the exhaust air side, which allows the liquid refrigerant to flow quickly back to the evaporator aided by the force of gravity. Generally, gross heat transfer efficiencies of up to 75% are claimed by manufacturers.

According to an embodiment of the invention, the term ‘Heat sink’ refers to any passive heat exchanger that cools a device by dissipating heat into the surrounding medium. It is in the scope of the invention wherein the heat sink is designed to maximize its surface area in contact with the cooling medium surrounding it, such as the air. Air velocity, choice of material, protrusion design and surface treatment are factors that affect the performance of a heat sink. Heat sink attachment methods and thermal interface materials also affect the die temperature of the integrated circuit. Thermal adhesive or thermal grease improve the heat sinks performance by filling air gaps between the heat sink and the heat spreader on the device.

It is also in the scope of the invention wherein heat sink materials are aluminum alloys. Aluminum alloy 1050A e.g., has one of the higher thermal conductivity values at 229 W/m*K but is mechanically soft. Aluminum alloys 6061 and 6063 are also useable, with thermal conductivity values of 166 and 201 W/m*K, respectively. The values depend on the temper of the alloy.

It is also in the scope of the invention wherein copper has excellent heat sink properties in terms of its thermal conductivity, corrosion resistance, biofouling resistance, and antimicrobial resistance. Copper has around twice the thermal conductivity of aluminum and faster, more efficient heat absorption. Its main applications are in industrial facilities, power plants, solar thermal water systems, HVAC systems, gas water heaters, forced air heating and cooling systems, geothermal heating and cooling, and electronic systems. Copper is three times as dense, and more expensive than aluminum. Copper heat sinks are machinable and skiveable.

It is also in the scope of the invention wherein diamond is useable, and its thermal conductivity of 2000 W/m·K exceeds copper five-fold. In contrast to metals, where heat is conducted by delocalized electrons, lattice vibrations are responsible for diamond's very high thermal conductivity. For thermal management applications, the outstanding thermal conductivity and diffusivity of diamond is an essential. Nowadays synthetic diamond is used as submounts for high-power integrated circuits and laser diodes.

It is also in the scope of the invention wherein composite materials are useable. Examples are a copper-tungsten pseudoalloy, AlSiC (silicon carbide in aluminum matrix), Dymalloy (diamond in copper-silver alloy matrix), and E-Material (beryllium oxide in beryllium matrix). Such materials are often used as substrates for chips, as their thermal expansion coefficient can be matched to ceramics and semiconductors.

According to an embodiment of the invention, the term ‘Heat pumps’ refers to a device that provides heat energy from a source of heat or “heat sink” to a destination. Heat pumps are designed to move thermal energy opposite to the direction of spontaneous heat flow by absorbing heat from a cold space and releasing it to a warmer one. A heat pump uses some amount of external power to accomplish the work of transferring energy from the heat source to the heat sink.

It is in the scope of the invention wherein the heat pump is a solid state heat pump (Pelletier module) using the thermoelectric effect have improved over time to the point where they are useful for certain refrigeration tasks.

According to an embodiment of the invention, the term ‘low emissivity’ (low e or low thermal emissivity) refers hereinafter to a surface condition that emits low levels of radiant thermal (heat) energy, provided e.g., by means of a special wavelength interval of radiant energy, namely thermal radiation of materials with temperatures approximately between 40 C to 60 C.

According to an embodiment of the invention, the term ‘thermal isolation’ and ‘thermal isolator’ interchangeably refers to means and methods for reduction of heat transfer (the transfer of thermal energy between objects of differing temperature) between objects in thermal contact or in range of radiative influence, such as fluorinated tin oxide. The said term also refers to thermal barrier coatings (TBC). It is in the scope of the invention wherein TBC consists of four layers: the metal substrate, metallic bond coat, thermally grown oxide, and ceramic topcoat. The ceramic topcoat is composed of e.g., yttria-stabilized zirconia (YSZ) which is desirable for having very low conductivity while remaining stable at nominal operating temperatures typically seen in applications. Rare earth zirconate having superior performance at temperatures above 1200° C., are further utilizable, however with inferior fracture toughness compared to that of YSZ. This ceramic layer creates the largest thermal gradient of the TBC and keeps the lower layers at a lower temperature than the surface. TBCs fail through various degradation modes that include mechanical rumpling of bond coat during thermal cyclic exposure, especially, coatings in aircraft engines; accelerated oxidation, hot corrosion, molten deposit degradation. There are issues with oxidation (areas of the TBC getting stripped off) of the TBC also, which reduces the life of the metal drastically, which leads to thermal fatigue. The TBC can be locally modified at the interface between the bondcoat and the thermally grown oxide so that it acts as a thermographic phosphor, which allows for remote temperature measurement; see Yu F. and Bennett T. D. (2005). “A nondestructive technique for determining thermal properties of thermal barrier coatings”. J. Appl. Phys. 97: 013520, which is incorporated herein as a reference.

In one embodiment of the invention, thermal isolation is provided by various means, including ceramic (Al₂O₃) compositions, ceramic layers coated with one or more thermal insulating layers (silver layers etc.). In another embodiment of the invention, the said thermal isolation s embedded with thermal insulators which actively efflux heat, such as heat pipes, heat pumps etc.

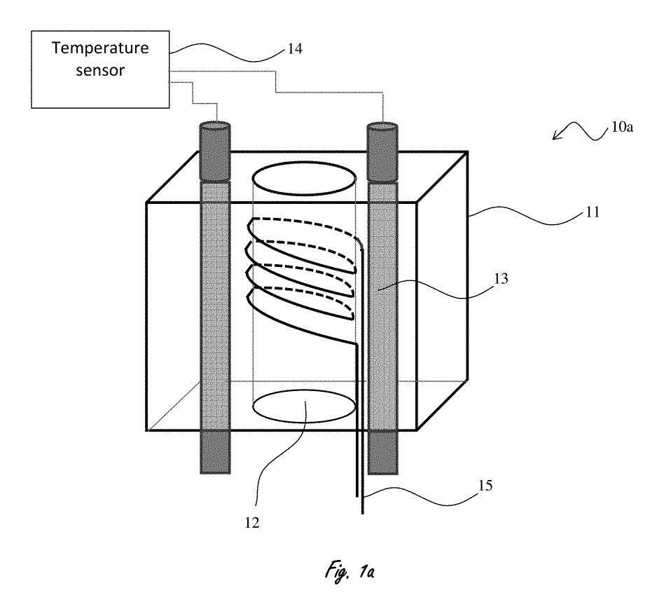

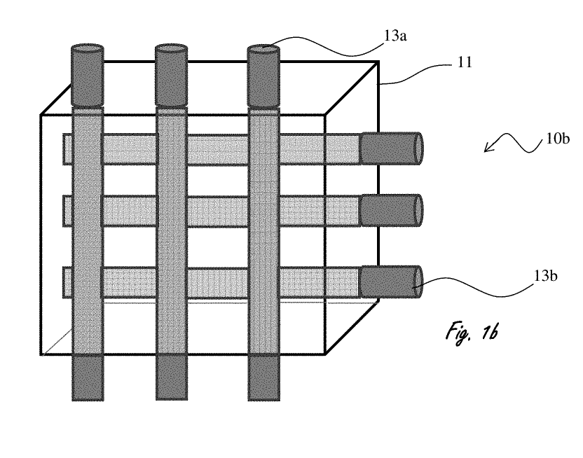

Reference is now made to FIG. 1a, presenting in an out-of-scale manner a heat sink (10a), e.g., a block of aluminum (11) having an open bore (12) in which a column (not shown) is affixed. A plurality of heat pipes (13) extended within said block. RF coils (15) are encircling e.g., in a coil like configuration, spiral wound configuration etc. said bore. The heat pipes, according to an embodiment of the invention, are effectively cooled in one (or two) of their ends thereby cooling block (11). The heat pipes, according to another embodiment of the invention, interconnected to a thermometer (14) thereby presenting blocks temperature.

Reference is now made to FIG. 1b, illustrating in an out-of-scale manner a heat sink (10b), e.g., condensate, glued or otherwise tableted comprising aluminum powder (11) comprising one or more sets (e.g., 13a, 13b), each of which comprising a plurality of heat pipes (13) extended within said block. The heat pipes, according to an embodiment of the invention, are effectively cooled in one (or two) of their ends thereby cooling block (11). The heat pipes, according to another embodiment of the invention, are arranged in 2D or 3D array, nets or assemblies, such as X:X and Y:Y bundles, spiral wound configuration etc.

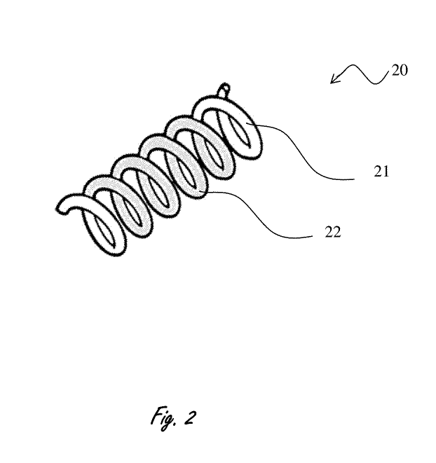

Reference is now made to FIG. 2, illustrating in an out-of-scale manner an RF coil (20) surrounding the imaging column at the VOI. According to an embodiment of the invention, at least one portion of the coil is coated, immersed, paint, doped, or otherwise contain effective layer of thermal insulator(s).

According to an embodiment of the invention, the RF coil comprises, is made of, or at least partially in contact with heat pipes. Hence, for example, flattened elongated cupper-made heat pipes are provided useful by texturizing, assembling, configuring or patterning as an RF coil assembly.

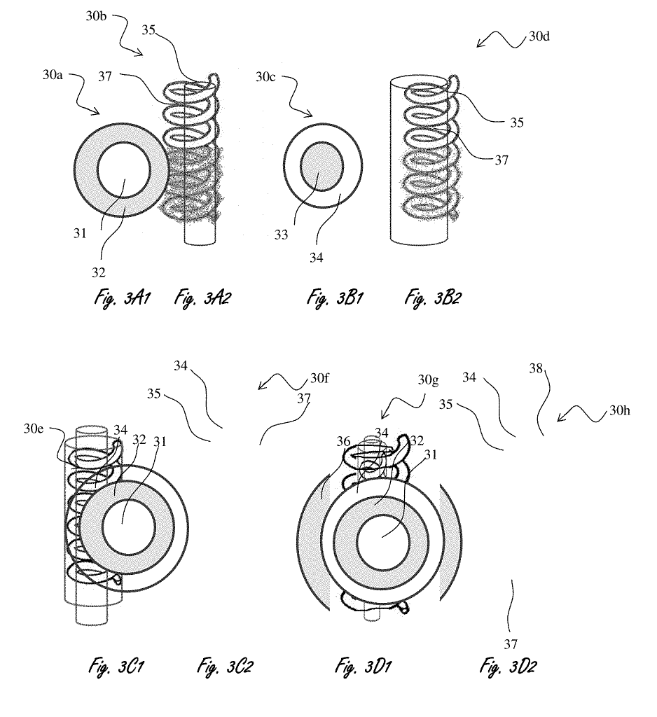

Reference is now made to FIGS. 3A1 to 3D2, illustrating in an out-of-scale cross-sections and perspective views of various imaging columns-RF coil configurations. FIG. 3A1 presents a cross section of an RF coil (32) surrounding a column (31); wherein FIG. 3A2 presents a perspective view of the same: RF coil (37) is provided externally to the column (35).

FIG. 3B1 presents a cross section of an RF coil (33) accommodated within a column (34); wherein FIG. 3B2 presents a perspective view of the same: RF coil (37) is provided within the column (35).

FIG. 3C1 presents a cross section of an RF coil (32) surrounding an imaging column (31) whilst it is simultaneously accommodated by one or more (similar or different) thermally isolating layers (35); wherein FIG. 3C2 presents a perspective view of the same: RF coil (37) is provided externally to the imaging column (34) and within external thermo isolating layer(s) (35). According to an embodiment of the invention, external layer (35) is a bundle of heat pipes having a circular cross-section.

FIG. 3D1 presents a cross section of a primary (inner) RF coil (32) surrounding an imaging column (31) whilst it is simultaneously accommodated by one or more (similar or different) thermally isolating layers (35). A secondary (external) coil enveloping the same and is provided for one or more utilizations, e.g., spiral wound arrangement of heat pipes, cooling pipe in which a cooling fluid is flown, gradient is provided etc. FIG. 3D2 presents a perspective view of the same: RF coil (37) is provided externally to the imaging column (34) and within external thermo isolating layer(s) (35), wherein external coil (38) is over-layering at least a portion of the same. According to an embodiment of the invention, external layer (35) is a bundle of heat pipes having a circular cross-section.

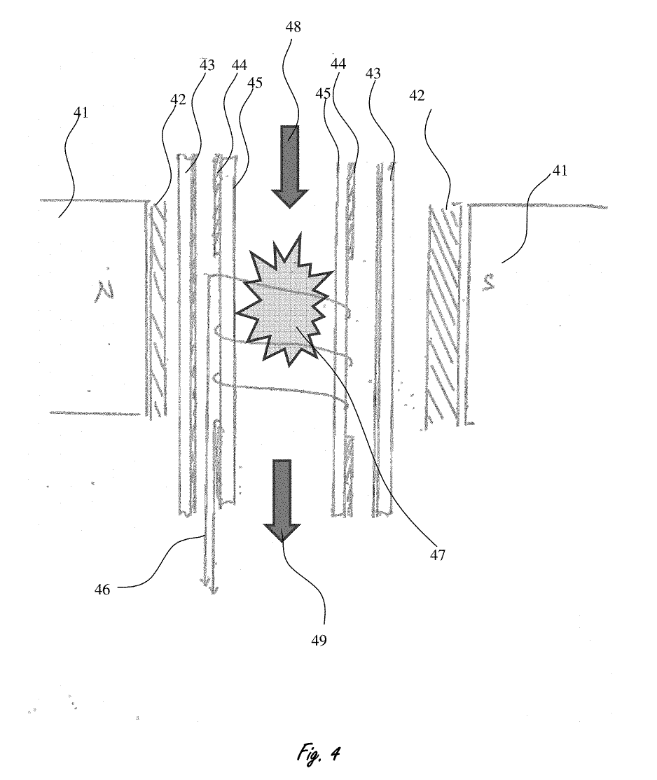

Reference is now made to FIG. 4, illustrating in an out-of-scale cross-section of an MRI comprising an open bore in which an imaging column is permanently or temporarily inserted. Within said column a sample is provided at MRI's VOI. This is a non-limiting example for using an MRI/NMR (MRD) and modules thereof, in both online and offline methods of magnet resonance imaging of samples, reactions and processes at high temperatures and/or high pressures. A carrier fluid, process fluid, examination fluid, reaction fluid (interchangeably referred hereinafter in short as ‘fluid’) is flown. The construction comprises, inter alia, a first pole piece (N, 41) heat sink module 42, made, e.g., as (i) a bundle of heat pipes (See e.g., 10b in FIG. 1A), and/or (ii) heat pump (e.g., a Pelletier module) etc. Another module (43) is a thermal insulator, made, e.g., from ceramic (Al₂O₃) compositions metal coating, comprising e.g., silver-made layer, commercially available VICTREX® PEEK-based coatings etc. Inner module (45) is possibly coated by layer (44). Such an inner tube-like open-tips envelope is made of strong and thermally insulating materials, such as polyether ether ketone (PEEK). It is in the scope of eth invention wherein such an inner tube-like column is provided in various diameters (e.g., from about 2 cm to about 8 cm; from about 8 to about 12 cm; from about 10 to about 16 cm etc.), sizes (column length ranges, e.g., from about 5 to about 25 cm; from about 20 to about 60 cm; from about 50 to about 120 cm etc.) and shapes (rounded, ovular or rectangular cross section, variable size and shape's cross section etc.).

It is well within the scope of the invention wherein the gap between an inner module (e.g., inner tube 45) and external module (e.g., outer concentric tube 43) is provided useful for further thermal insulation. According to one embodiment of eth invention, thermal insulating fluid is either flown or fixedly provided; such as Aragon or Nitrogen gasses. Alternatively, an effective vacuum (low pressure) environment is provided in said gap. Such a low pressure is actively provided (e.g., by means of a vacuum pump), or otherwise passively (stable) achieved.

Reference is still made to FIG. 4, where at least one RF coil (46) is provided, here, externally to inner tube (45). RF coil is interconnected via conductive cables. The RF coil is made, according to an embodiment of the invention, of heat pipes. Advantages of cooling the RF coils are twofold: (i) improving quality factors (Q) at low temperature, see Ocali, Ogan, and Ergin Atalar “Ultimate intrinsic signal to noise ratio in MRI”, Magnetic resonance in medicine 39.3 (1998): 462-473, which is incorporated herein as a reference; and (ii) provided as an effective heat sink. More than that. The RF coil location increase feeling factor, see Poulichet, Patrick, et al. “Optimisation and realisation of a portable NMR apparatus and micro antenna for NMR.” Design, Test, Integration and Packaging of MEMS/MOEMS (DTIP), 2011 Symposium on. IEEE, 2011, which is incorporated herein as a reference.

It is further within the scope of the invention wherein pole pieces (41) are heated to magnet temperature, e.g., a temperature between about 40 C to 45 C. Such heating is decreasing heat gradient. Hence for example and in a non-limiting manner, in case sample temperature is ranging from 130 C to 170 C and magnet temperature is ranging between ambient temperature to 45 C, ΔT across the imaging system decreases between 110 C-150 C; to 90 C-130 C, namely about 20%.

Reference is still made to FIG. 4, where sample 47 is imaged at high temperature and high pressure. According to an embodiment of the invention, the sample is a rock comprising oil, processed in high temperature high pressure conditions, see Chinese patent application CN 101907586 High-temperature high-pressure clamp for testing rock core by nuclear magnetic resonance; U.S. Pat. No. 8,791,695, Magnetic resonance apparatus and method; U.S. Pat. No. 8,763,710, Method for integrated enhanced oil recovery from heterogeneous reservoirs; U.S. Pat. No. 6,178,807, Method for laboratory measurement of capillary pressure in reservoir rock; US patent application 20130091941, Determination of oil saturation in reservoir rock using paramagnetic nanoparticles and magnetic field; all are incorporated herein as a reference. Oil in sample 47 is thus provided by means of processing fluids, such as steam, in high temperature high pressure conditions. It is in the scope of the invention, wherein said fluids which are forcefully pushed or pressed (48) at high pressure (e.g., about 8,000 to about 12,000 PSI) towards said sample are hydrogen free compositions, such as Aragon and Nitrogen. Additionally or alternatively, an effective low pressure is applied (49).

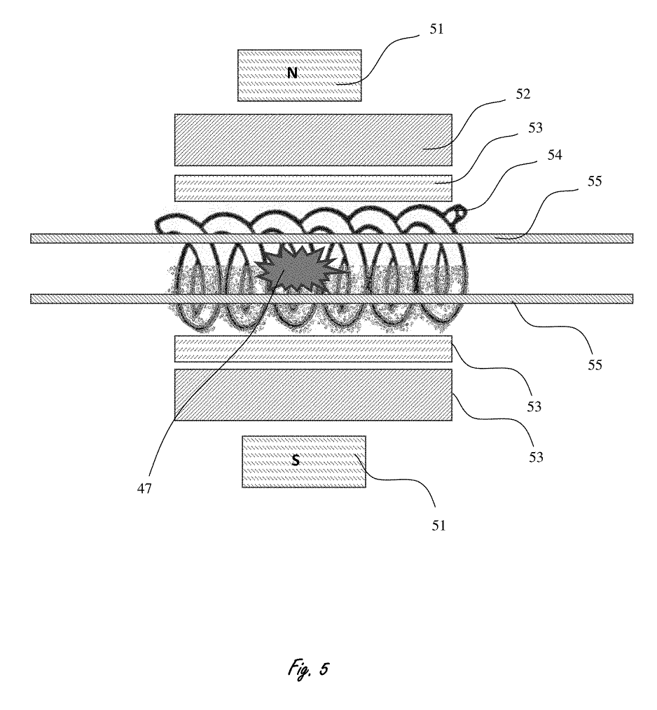

Reference is now made to FIG. 5, illustrating in an out-of-scale manner another cross-section of an MRD and modules thereof, and to both online and offline methods of magnet resonance imaging of samples, reactions and processes at high temperatures and/or high pressures. The device comprises, inter alia, pole piece (51); heat sink (53), heat insulator (53) and inner imaging column (also known as imaging probe or process probe, 55). Sample 47 is provided within said probe and surrounded by an RF coil (not shown). Probe 55 is made of PEEK or any other suitable materials, coated or not by at least one polytetrafluoroethylene (PTFE, a commercially available Teflon® product, not shown) layer. Probe (55) is further enveloped, housed or surrounded by a cooling coil (54), whereat effective heat exchange is provided.

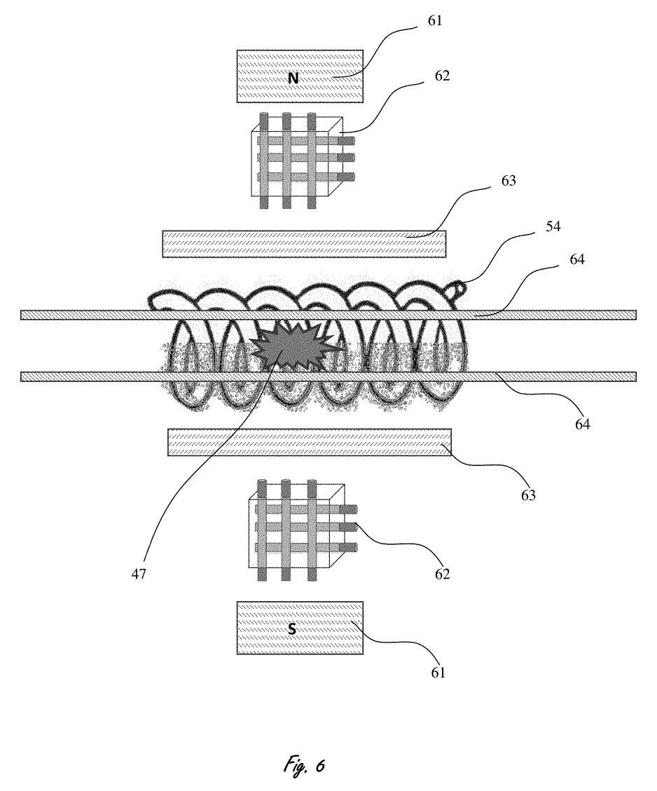

Reference is now made to FIG. 6, illustrating in an out-of-scale manner another cross-section of an MRD and modules thereof, and to both online and offline methods of magnet resonance imaging of samples, reactions and processes at high temperatures and/or high pressures. The device comprises, inter alia, pole piece (61); heat sink (62), heat insulator (63) and inner imaging column (55). Sample 47 is provided within said probe and surrounded by an RF coil (not shown); and is further surrounded by a cooling coil (64), whereat effective heat exchange is provided. Here heat sink 62 is made of heat pipes' mesh housed in aluminum block.

It is in the scope of the invention wherein SNR at such high-temperature high-pressure conditions is increased by mans of said MRD and modules thereof. In an embodiment of the invention, gradient coils are imbedded with RF coils. In another embodiment of the invention, a “sandwich”-like gradient/RF/gradient coils arrangements are used. In another embodiment of the invention, gradient coils, provided adjacent to pole pieces, are facing the imaging probe via a thermal insulation layer. In another embodiment of the invention, MRI-safe (MRI-transparent) aluminum granules coated by thermoplastic compositions are utilized as mirrors to enhance gradient coil function without causing Eddy current.

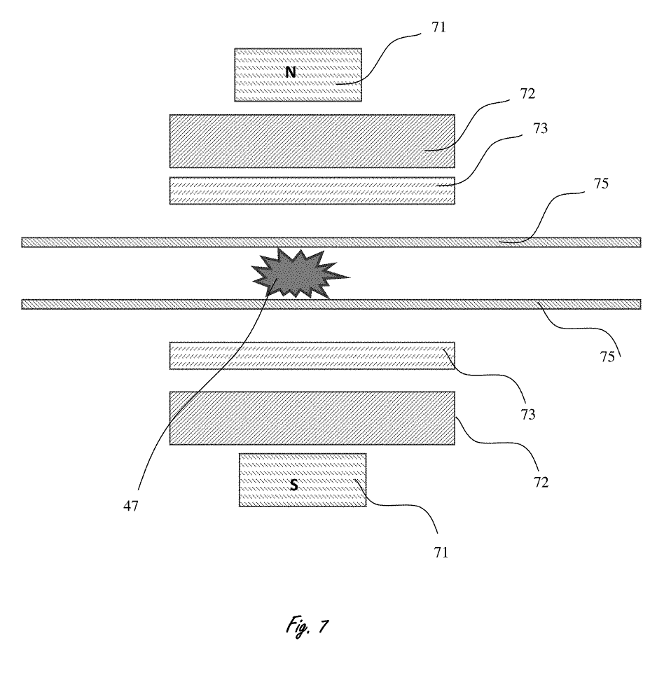

Reference is now made to FIG. 7, illustrating in an out-of-scale manner another cross-section of an MRD and modules thereof, and to both online and offline methods of magnet resonance imaging of samples, reactions and processes at high temperatures and/or high pressures. The device comprises, inter alia, pole piece (71); heat sink (72), gradient coils (73) and inner imaging column (55). Sample 47 is provided within said probe and surrounded by an RF coil (not shown). Here, gradient coils are well insulated by means of MRI-safe and transparent metal granules in thermoplastic bulk, as described in U.S. Pat. No. 6,913,827, Nanocoated primary particles and method for their manufacture; U.S. Pat. No. 6,090,728 EMI shielding enclosures; and PCT application WO 2008043373, Heat insulating composite and methods of manufacturing thereof, all of which are incorporated herein as a reference.

It is also in the scope of the invention wherein imaging provided in aforesaid MRD systems and modules thereof are provided in one or more techniques: T1/T2 analysis with non-homogeneous magnetic field; FT spectroscopy; CW spectroscopy and 2D/3D imaging.

It is also in the scope of the invention wherein imaging provided in aforesaid MRD systems and modules thereof are provided in one or more techniques: logarithmic amplification, e.g., as disclosed in U.S. Pat. No. 7,075,366, Methods and systems for stabilizing an amplifier; U.S. Pat. No. 8,461,842, Methods and systems for stabilizing an amplifier; U.S. Pat. No. 4,994,746, Method of and apparatus for nuclear magnetic resonance analysis using true logarithmic amplifier, all are incorporated herein as a reference. Alternatively or additionally, other known techniques, such as utilizing shaped pulses, water vs MRI-inert molecules are used.

The invention is not intended to be limited to the preferred embodiment thereof described above or the Example described above, which are meant to be illustrative rather than exhaustive. Also, certain changes and modifications of the embodiments of the invention herein disclosed will be readily apparent to those of skill in the art. It is the applicant's intention to cover by the claims all such changes and modifications which could be made to the embodiments of the invention herein chosen for the purposes of disclosure which do not depart from the spirit and scope of the invention.

1. MRI/NMR systems, devices and modules thereof for T1/T2 analysis; FT spectroscopy; CW spectroscopy and 2D/3D imaging of samples, process and reactions at high temperatures and/or high pressures, comprising active and/or passive thermal insulating means as described in the description and figures.

2. MRI/NMR systems, devices and modules thereof for T1/T2 analysis; FT spectroscopy; CW spectroscopy and 2D/3D imaging of samples, process and reactions at high temperatures and/or high pressures, comprising active and/or passive SNR increasing means as described in the description and figures.

3. A method of providing T1/T2 analysis; FT spectroscopy; CW spectroscopy and 2D/3D imaging of samples, process and reactions at high temperatures and/or high pressures, comprising step of inline or offline active and/or passive thermal insulating the same as described in the description and figures.

4. A method of providing T1/T2 analysis; FT spectroscopy; CW spectroscopy and 2D/3D imaging of samples, process and reactions at high temperatures and/or high pressures, comprising step of inline or offline active and/or passive SNR increasing the same as described in the description and figures.
